(19) United States
(12) Patent Application Publication
(10) Pub. No.: US 2025/0307679 A1
(43) Pub. Date: Oct. 2, 2025

(54) SUPERCONDUCTING QUANTUM CIRCUIT APPARATUS

(71) Applicant: NEC Corporation, Tokyo (JP)

(72) Inventor: Akira MIYATA, Tokyo (JP)

(73) Assignee: NEC Corporation, Tokyo (JP)

(21) Appl. No.: 19/069,427

(22) Filed: Mar. 4, 2025

(30) Foreign Application Priority Data
Mar. 28, 2024 (JP) 2024-054301

(51) Int. Cl. G06N 10/40; H10N 60/12

(52) U.S. Cl. CPC G06N 10/40; H10N 60/12

(57) ABSTRACT

Provided a first chip including a qubit circuit including a SQUID in a wiring layer formed on a substrate of the first chip; and a second chip including a wiring layer on a first side of a substrate of the second chip, the wiring layer on the first side disposed opposed to the wiring layer of the first chip, the wiring layer of the first chip including an opening juxtaposed with the SQUID, the wiring layer on the first side of the second chip including a first wiring having one end connected to a terminal, and in a region opposite at least the opening of the first chip, being extended along the qubit circuit of the first chip, the first wiring having other end connected to a ground pattern arranged in the wiring layer on the first side of the second chip.

### FIELD

### Cross Reference to Related Applications

This application is based upon and claims the benefit of the priority of Japanese patent application No. 2024-054301, filed on Mar. 28, 2024, the disclosure of which is incorporated herein in its entirety by reference thereto.

The disclosure relates to a superconducting quantum circuit apparatus.

### BACKGROUND

A quantum bit (qubit) made up of a superconducting quantum circuit, generally includes a planar circuit of superconducting material formed on a surface of a semiconductor substrate by using, for example, vapor deposition, and a nonlinear inductor, such as a superconducting quantum interference device (SQUID) which includes multiple Josephson junctions in a loop. A state of a superconducting quantum bit (qubit) is controlled by applying a magnetic field to the SQUID loop of the qubit. Patent Literature (PTL) 1 discloses a quantum device that includes a first chip with a qubit(s) on a first side of a substrate thereof and a second chip with a coil wiring (current path for applying a magnetic field) configured to generate a magnetic field on a first side of the substrate thereof, wherein a central axis of the coil wiring of the second chip and a central axis of the SQUID loop of the qubit of the first chip are aligned so that they overlap. The quantum device is equipped with a three-dimensional wiring structure in which the first side of the first chip is bonded opposite to the first side of the second chip, with the first side of the first chip aligned with the first side of the second chip
PTL 1: U.S. Pat. No. 10,950,654B2

### SUMMARY

In such a structure as in PTL 1, wherein the center axis of the coil wiring of the second chip is aligned with the center axis of the SQUID loop of the qubit circuit of the first chip, as in PTL 1, in case that the first chip and the second chip are narrow spaced, a capacitance between the SQUID loop of the first chip and the coil wiring of the second chip is likely to be large. As a result, there is a trade-off between a strength of the magnetic field coupling between the SQUID loop of the first chip and the coil wiring of the second chip and a magnitude of an internal Q-value, which is a performance index of the qubit circuit, which is difficult to achieve both.

It is one of objects of the present disclosure to provide a superconducting quantum circuit apparatus enabled to secure a strength of a magnetic field coupling between a SQUID loop of a first chip's qubit circuit and a wiring of a second chip and to ensure a desired internal Q-value, which is a performance index of the first chip's qubit circuit.

In accordance with one of embodiments of the present disclosure, a superconducting quantum circuit apparatus includes a first chip that includes a qubit circuit including a superconducting quantum interference device (SQUID) in a wiring layer formed on a substrate of the first chip; and a second chip that includes a wiring layer on a first side of a substrate of the second chip, the wiring layer on the first side being disposed opposed to the wiring layer of the first chip, wherein the wiring layer of the first chip has an opening juxtaposed with the SQUID of the qubit circuit, and wherein the wiring layer on the first side of the second chip includes a first wiring having one end connected to a terminal, and in a region opposite at least the opening of the first chip, being extended along the qubit circuit of the first chip, the first wiring having other end connected to a ground pattern arranged in the wiring layer on the first side of the second chip.

According to the present disclosure, it is made possible to secure a strength of a magnetic field coupling between a SQUID loop of a qubit circuit of a first chip and a wiring of a second chip and also to ensure a desired internal Q-value, a performance index of the qubit circuit of the first chip.

### BRIEF DESCRIPTION OF DRAWINGS

FIG. 1A and FIG. 1B illustrate a comparative example.

FIG. 2A and FIG. 2B illustrate the comparative example.

FIG. 3A and FIG. 3B illustrate the comparative example.

FIG. 4A and FIG. 4B illustrate an example of at least one of example embodiments of the present disclosure.

FIG. 5A and FIG. 5B illustrate an example of at least one of example embodiments of the present disclosure.

FIG. 6 illustrates an example of at least one of example embodiments of the present disclosure.

FIG. 7 illustrates an example of at least one of example embodiments of the present disclosure.

FIG. 8 illustrates a simulation result of at least one of example embodiments of the present disclosure.

FIG. 9A through FIG. 9C illustrate an example of at least one of example embodiments of the present disclosure.

FIG. 10A through FIG. 10C illustrate an example of at least one of example embodiments of the present disclosure.

FIG. 11A through FIG. 11C illustrate an example of at least one of example embodiments of the present disclosure.

FIG. 12 illustrates an example of at least one of example embodiments of the present disclosure.

### EXAMPLE EMBODIMENTS

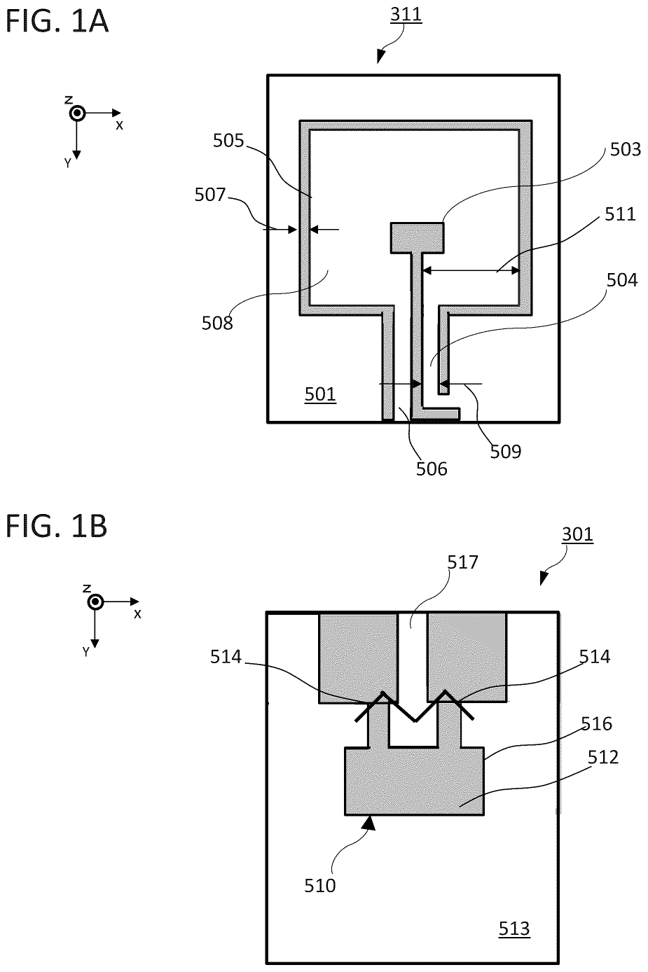

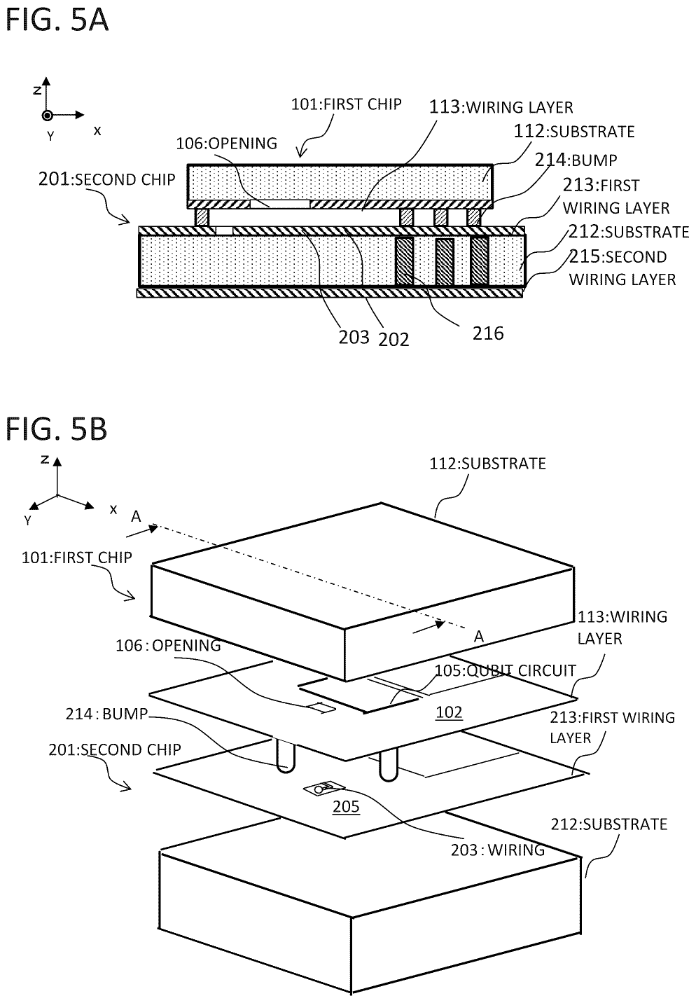

The following describes some embodiments of the present disclosure. At the outset, as a premise of present disclosure, an analysis by the inventor of a quantum device disclosed in PTL 1 is given as a comparative example. FIGS. 1A and 1B are based on drawings of the quantum device disclosed in FIGS. 5A, 5B, etc. of PTL 1. FIG. 1A is a plan view schematically showing a wiring layout of a second chip 311, and FIG. 1B is a plan view 20 schematically showing a wiring layout of a first chip 301. In FIGS. 1A and 1B, white areas correspond to areas where a layer of superconducting material exists, and gray areas correspond to areas where no superconducting material exist and a substrate of the chip may be exposed.

Referring to FIG. 1A, in the second chip 311, a coil wiring (bias coil) formed on a superconductor layer includes a first portion 504 coupled to a superconductor ground plane 501, a second portion 506 coupled to a signal source that provides a control signal during device operation, and a loop section 508. The loop portion 508 of the coil wiring includes an inner loop edge 503 and an outer loop edge 505. The outer loop edge 505 is opposite (separated from) the edge of the superconductor ground plane 501 via a gap 507. As shown in FIG. 1A, in the second chip 311, a width 509 of the superconductor material in the first portion 504 and second portion 506 is much narrower than a width 511 of the superconductor material in the loop 508. A ground connection is made in the area where the bias wire is shorted to provide a proper path for a return current. For example, unshown bumps (ground bumps) are provided on both sides of the coil wiring.

FIG. 1B is a schematic illustration of a top view of an example SQUID region 510 of a superconducting qubit in the first chip 301. In the example shown in FIG. 1B, the SQUID within the SQUID region 510 is physically coupled to a central region of a n un shown superconducting qubit, from which a wiring 517 extends between superconducting qubits. The SQUID region 510 includes a layer of superconductor material arranged in a generally ring shape, which superconductor material is interrupted at multiple locations, and Josephson junctions 514 are provided in the interrupted gaps. A superconducting wiring of the Josephson junction 514 is depicted in black. A part of the SQUID region 510 may be formed by a superconducting ground plane 513. The SQUID region 510 has an inner ring region 512 in which no superconductors are present.

An area/perimeter of the inner ring region 512 is defined by an edge 516 of the superconductor material. During operation of the device, the coil wiring of the second chip 311 is electromagnetically coupled (inductively coupled) to the SQUID in the SQUID region 510. When a control current is applied to the coil wiring of the second chip 311, the operating frequency of the qubit can be adjusted by inductive coupling.

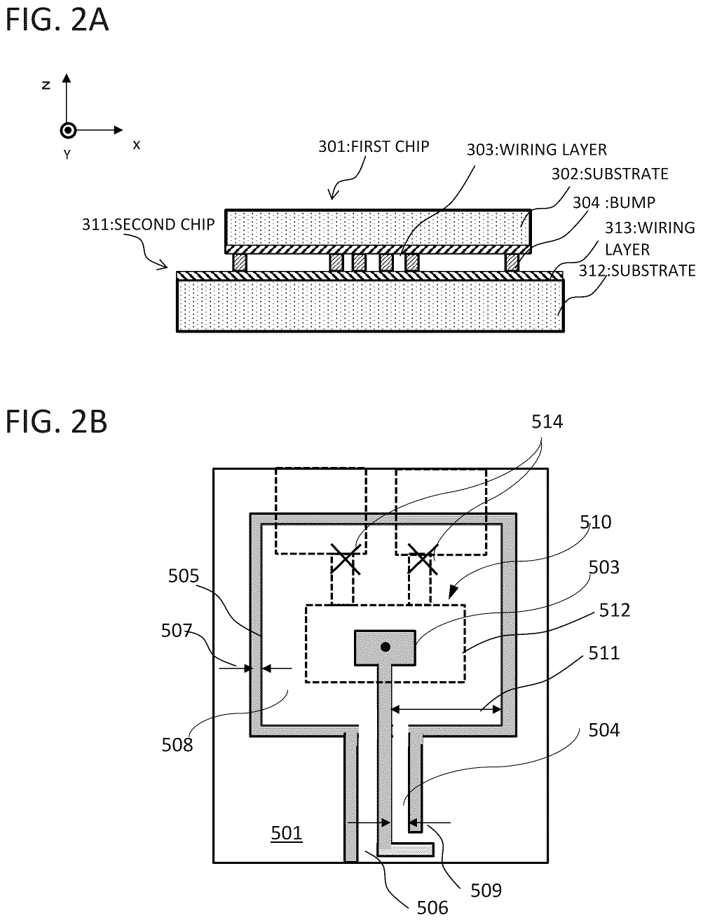

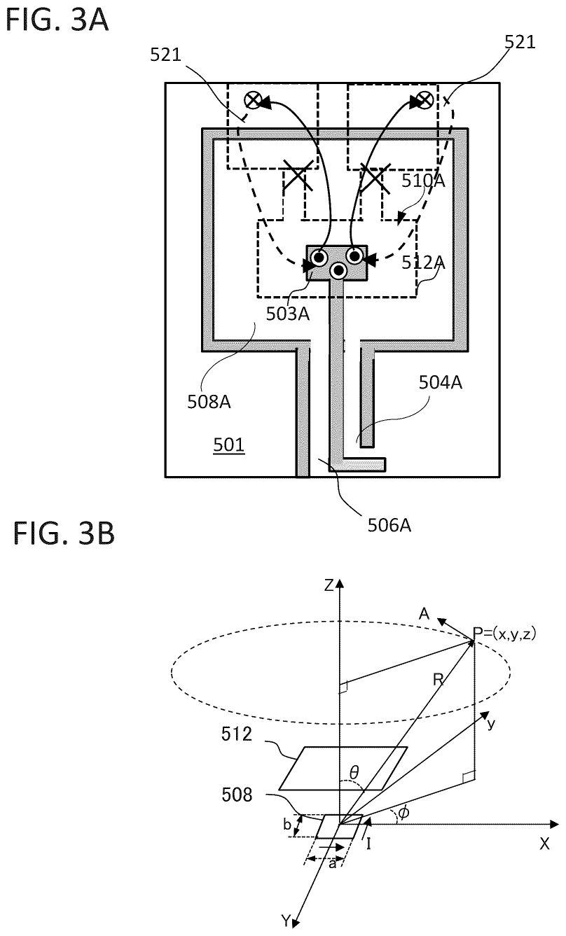

As shown in FIG. 2A as a schematic cross-sectional view, the first chip 301 is placed on top of the second chip 311 and is electrically and/or mechanically connected using bumps 304. The bump 304 may include superconducting material. FIG. 2A corresponds to FIG. 3A of PTL 1. FIG. 2B illustrates the overlapping of the wiring layers of the first chip 301 and the second chip 311 stacked as shown in FIG. 2A. FIG. 2B corresponds to FIG. 5A of PTL 1. FIG. 2B shows that when the inner loop edge 503 and outer loop edge 505 of the second chip 311 are aligned and bump-jointed with the first chip 301 and the second chip 311, the inner loop edge 503 is in the SQUID region 510 of the superconducting qubit on the first chip 301 0 on the second chip 311 so that it is included within the inner ring region 512 of the first chip 301. The outer loop edge 505 is formed on the second chip 311 such that when the first chip 301 and the second chip 311 are aligned, the inner ring region 512 of the SQUID region 510 of the superconducting qubit on the first chip 301 is completely included by the outer loop edge 505 of the loop section 508 on the second chip 311 formed in such a way. In FIG. 2B, the center of the inner loop edge 503 of the second chip 311 and the center of the inner ring region 512 of the SQUID region 510 of the superconducting qubit on the first chip 301 are overlapped and joined.

When a center of the coil wiring of the loop section 508 surrounded by the inner loop edge 503 and an outer loop edge 505 of the second chip 311 (center of the inner loop edge 503) and a center of the inner ring region 512 of the qubit circuit of the first chip 301 are aligned as described above, as schematically shown in FIG. 3A, a magnetic force (magnetic force line) 521 generated by the current (loop current) flowing in the loop section 508 of the second chip 311 penetrates an inner ring region 512A of the qubit circuit of the first chip 301, forms a closed path through the substrate from an area where the substrate is exposed without superconducting material in the first chip 301. When a height of bump 304 is equal to or smaller than the gap 507, the nearest conductor from the loop 508 of the second chip 311 is the wiring (superconductor) 517 of the first chip 301, and a capacitance between the wiring (superconductor) 517 of the first chip 301 and the loop 508 of the second chip 311 becomes non-negligible and an unintended behavior appears, one of which is that a signal frequency of the qubit is more likely to pass between the qubit and the second part 506 which is coupled to the signal source providing the control signal, thus lowering an internal Q-value of the superconducting qubit, which is a problem

FIG. 3B illustrates a vector potential A generated by the current flowing in the loop portion 508 surrounded by the inner loop edge 503 and outer loop edge 505 of the second chip 311. Letting long and short sides of a rectangular-shaped inner loop edge 503 of the second chip 311 be a and b, and the current flowing in the loop section 508 be I, a magnitude of the vector potential A is proportional to μ=Iab, which is a current I multiplied by an area of the inner loop edge 503 (rectangular area with a width: a and a height: b). This μ is called a magnetic moment. The inner loop edge 503 can be a circle, triangle, etc. The vector potential A at a position P(x,y,z) (distance R (=√(x²+y²+z²) from the center of the loop 508) is given by (ε0 is the dielectric constant of vacuum and c is the speed of light).

$$\vec{A} = \frac{1}{4 π {ε}_{0} {c}^{2}} \frac{\vec{μ} \times \vec{R}}{{R}^{3}} \qquad ( 1 )$$

### From

$$\vec{B} = r o t \vec{A} \qquad ( 2 )$$

The magnetic field (vector) B=(Bₓ, B_{y}, B_{z}) is given as

$${B}_{x} = \frac{δ {A}_{z}}{δ y} - \frac{δ {A}_{y}}{δ z} = \frac{1}{4 π {ε}_{0} {c}^{2}} \frac{3 xz}{{R}^{3}} \qquad ( 3 )$$

$${B}_{y} = \frac{δ {A}_{x}}{δ z} - \frac{δ {A}_{z}}{δ x} = \frac{1}{4 π {ε}_{0} {c}^{2}} \frac{3 yz}{{R}^{5}} \qquad ( 4 )$$

$${B}_{z} = \frac{δ {A}_{y}}{δ x} - \frac{δ {A}_{x}}{δ y} = - \frac{1}{4 π {ε}_{0} {c}^{2}} ( \frac{1}{{R}^{3}} - \frac{3 {z}^{2}}{{R}^{5}} ) \qquad ( 5 )$$

From FIG. 3B, the inner ring region 512 of the SQUID region 510 of the first chip 301 is wider than the inner loop edge 503 of the second chip 311. The magnetic field generated by the current (loop current) flowing in the loop section 508 surrounded by the inner loop edge 503 and outer loop edge 505 of the second chip 311 depends on a distance between the second chip 311 and the first chip 301, a size of the rectangular-shaped inner loop edge 503 of the second chip 311 and the first chip. The magnetic field may spread over a wide area in all four directions of the inner ring region 512, depending on a size of the inner ring region 512 of the SQUID region 510 of the chip 301. Note that the magnetic fields Bx and By in the x and y directions are proportional to (1/R)³. If the z-axis value z is a distance between the opposing surfaces of the first chip 301 and the second chip 311, and the value of z is small with respect to R, Bz in the z-axis direction is approximated by (1/R)³, and the magnitude of the magnetic field B at the point P decreases with a third power of the distance R from the center of the loop current. For example, the magnetic field at a location twice the distance P from the center of the loop current decreases by a factor of eight.

The above issue is one example, but according to the present disclosure, in applying a magnetic field to a qubit in various situations, not limited to the above, a magnetic field application structure that ensures a magnetic field coupling strength between the SQUID loop of the first chip and the wiring of the second chip is provided that enables a desired internal Q-value, a performance index of the qubit.

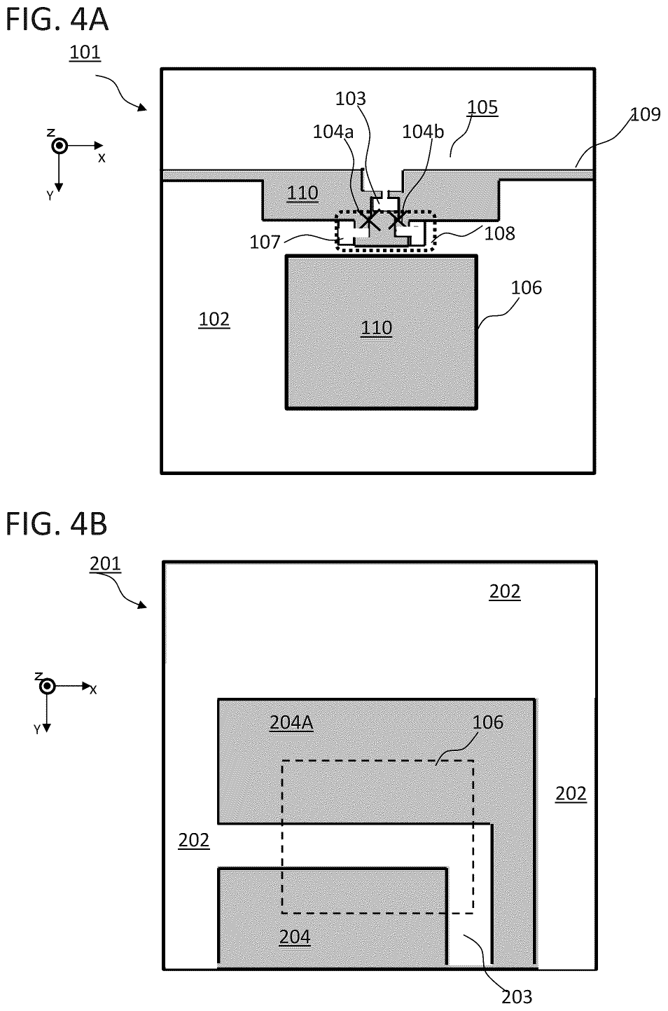

FIG. 4A is a schematic plan view of a wiring pattern of a wiring layer of a first chip 101 of the present disclosure, viewed from above. In FIG. 4A, a white area corresponds to an area where a wiring layer of the superconducting material exists and a gray area designated by a reference numeral 110 corresponds to an area where no superconducting material exists (such as a void in the wiring layer) and a substrate of the first chip 101 may be exposed. Referring to FIG. 4A, the first chip 101 includes at least two Josephson junctions 104a and 104b that bridge a wiring 103 of the qubit circuit 105 and ground in parallel. The wiring 103 is made of superconducting material which may serve as an electrode with one end of each of the Josephson junctions 104a and 104b respectively connected thereto. The qubit circuit 105 is connected to an input/output line (readout line) not shown. An electrode on the ground side to which each of other ends of Josephson junctions 104a and 104b connects includes a wiring 107 and a half (semi)-rectangular (an upper side of the drawing is an open ended) ground electrode 108 (the ground plane surrounded by a dashed line). The ground electrode 108 may be integrated with a ground surface 102 and formed by patterning the ground surface 102 as shown in FIG. 4A. Although not limited thereto, Josephson junctions 104a and 104b may be formed by forming a first aluminum film on the surface of the substrate of the first chip 101 by oblique deposition, oxidizing the first aluminum film to form a tunnel oxide film (AlOₓ) and forming a second aluminum film by oblique deposition from a direction opposite to the previous one, thus forming a Josephson junction (Al/AlOₓ/Al).

In the present disclosure, the half-rectangular ground electrode 108 is located at the most remote position in the SQUID loop, opposite the wiring 103 of the qubit circuit. The wiring 103 of the qubit circuit 105, the Josephson junctions 104a and 104b, the superconducting member (wiring) 107 and the half-rectangular ground electrode 108 constitute a SQUID loop. An opening 106 is provided in the ground plane 102 of the wiring layer of the first chip 101 adjacent to the semi-rectangular ground electrode 108 of the SQUID loop. This opening 106 may be formed by etching or otherwise to remove the wiring layer formed on the substrate in the shape of this opening, exposing the substrate surface directly below the wiring layer. The first chip 101 is also called a quantum chip because it is equipped with a qubit circuit 105.

FIG. 4B is a schematic plan view of the first wiring layer of the second chip 201 of the present disclosure, viewed from above. The first chip 101 in FIG. 4A is face-down mounted with the wiring layer thereof facing the first wiring layer of the second chip 201. FIG. 4B illustrates an area of the first wiring layer of the second chip 201 corresponding to the area of the first chip 101 in FIG. 4A. The second chip 201 is also referred to as a wiring chip or interposer.

In the first wiring layer of the second chip 201, there is provided a wiring 203 that overlaps in part with an area on one side (right side in the drawing) of the opening 106 (shown in dashed lines) of the first chip 101. The other end of the wiring 203 is connected to a signal source. The wiring 203 is extended to the bottom of the drawing and connected to a signal terminal (pad) to which a signal from an unshown signal source is supplied, and is bent by 90 degrees within an area corresponding to the opening 106 of the first chip 101, crosses the opening 106, and is connected to the ground 202 at the other side (left side of the drawing) of the opening 106. The ground 202 of the wiring layer is also referred to as a ground plane or ground pattern. In an area 204 between the wiring 203 and the ground 202, a substrate surface is exposed.

The ground pattern 202 to which one end of the wiring 203 connects is connected to the ground pattern 202 on the right side of the drawing in a downward U-shaped pattern on the upper left side of FIG. 4B, surrounding the SQUID connecting to the opening 106 and the qubit circuit of the first chip 101 in FIG. 4A. The right side ground pattern 202 is extended downward in the drawing along the wiring 203 to the unshown signal terminal to which the wiring 203 connects, enclosing the unshown signal terminal and reaching the ground pattern 202 on the left side of the drawing. The area 204A surrounded by the wiring 203 and the ground pattern 202 is laid out such that when the first chip 101 in FIG. 4A is face-down mounted, the SQUID loop of the first chip 101 is located within the area 204A (where the first wiring layer is deleted).

FIG. 5A schematically illustrates an example of a cross-sectional view of the flip-chip mounting in which the wiring layer of the first chip 101 in FIG. 4A faces the wiring layer of the second chip 201 in FIG. 4B. FIG. 5B is a schematic diagram illustrating a disassembled diagonal view of the flip chip mounting with the wiring layer of the first chip 101 in FIG. 4A facing the wiring layer of the second chip 201 in FIG. 4B. In FIG. 5B, the wiring layer 113 of the first chip 101 and the first wiring layer 213 of the second chip 201 are schematically shown separated from the substrate 112 and 212, respectively. Note that bumps are partially shown. FIG. 5A corresponds to a cross-section of the A-A line (parallel to the x-axis) of FIG. 5B viewed from the y-axis direction. The wiring 203 of the first wiring layer 213 of the second chip 201 traverses the rectangular-shaped opening 106 of the wiring layer 113 of the first chip 101 (an area where no wiring pattern is provided) from one end to the other end, directly under the opening 106 of the first chip 101. In FIG. 5B, the second wiring layer 215 of the second chip 201 and the via 216 that penetrates the substrate 212 of the second chip 201 in FIG. 5A are not shown.

The substrate 112 of the first chip 101 comprises, for example, a silicon substrate. The wiring layer 113 is created by the wiring pattern formation process of the semiconductor process (formation (deposition) of a superconducting thin film, resist coating, exposure/development, etching, etc.). The second chip (interposer) 201 has a first wiring layer 213 and a second wiring layer 215 on the first and second sides of the substrate 212, respectively. The substrate 212 comprises, for example, a silicon substrate. As a non-limiting example, the substrate 112 of the first chip 101 and the substrate 212 of the second chip 201 are not limited only to silicon, but also sapphire or compound semiconductor materials (Group IV (GeSn, etc.), Group III-V (GaAs, GaN, GaP, 11 GaSb, InAs, InP, InS, etc.), Group II-VI (ZnS, ZnSe, etc.)) and other electronic materials may be used. Single crystal may be preferably used, but polycrystalline or amorphous may also be used.

The wiring layer 113 of the first chip 101 is composed of niobium (Nb), niobium nitride, aluminum (aluminium) (Al), indium (In), lead (Pb), tin (Sn), rhenium (Re), palladium (Pd), titanium (Ti), tantalum (Ta), tantalum nitride, and at least one of these Superconductive materials consist of superconducting materials such as niobium (Nb) alloys containing at least one of these. The superconducting material is not limited to niobium (Nb), but may also include niobium nitride, aluminum (Al), indium (In), lead (Pb), tin (Sn), rhenium (Re), palladium (Pd), titanium (Ti), titanium nitride, tantalum (Ta), tantalum nitride, and alloys containing at least one of these. The alloy may include at least one of the following. It may be the same superconducting material as the first and second wiring layers 213 and 215 of the second chip 201, or it may include wiring of a normal-conducting member. Bumps 214 are protrusions suitable for controlling the height of the substrate spacing to be bonded, as shown in the figure, and can be selected in any shape, such as columnar (cylindrical, polygonal, etc.), pyramidal (which can include conical and square pyramids as well as cones, pyramids, etc.), spherical, rectangular, etc. The bump 214 may have a top thereof molded to make a part of the top almost flat. The bump 214 may be made of a normal-conductive material such as copper or silicon dioxide (SiO2), for example, and its surface may be covered with a film of superconductive material.

In FIG. 5A, the second wiring layer 215 side of the second chip 201 is connected to an unshown printed circuit board wiring layer, the terminal 217 of the first wiring layer 213 of the second chip 201 is connected to an unshown terminal on the second wiring layer 215 side via a through-via 216, and from a connector on the printed circuit board, an unshown It may be configured to connect to an unshown signal source or the like via a coaxial cable or the like. Alternatively, the second wiring layer 215 of the second chip 201 may be configured as a ground pattern, and the terminal 217 of the first wiring layer 213 of the second chip 201 may be connected via a wiring to the peripheral terminal (pad) of the second chip 201 and connected to a terminal on the unshown printed board by wire bonding or other means.

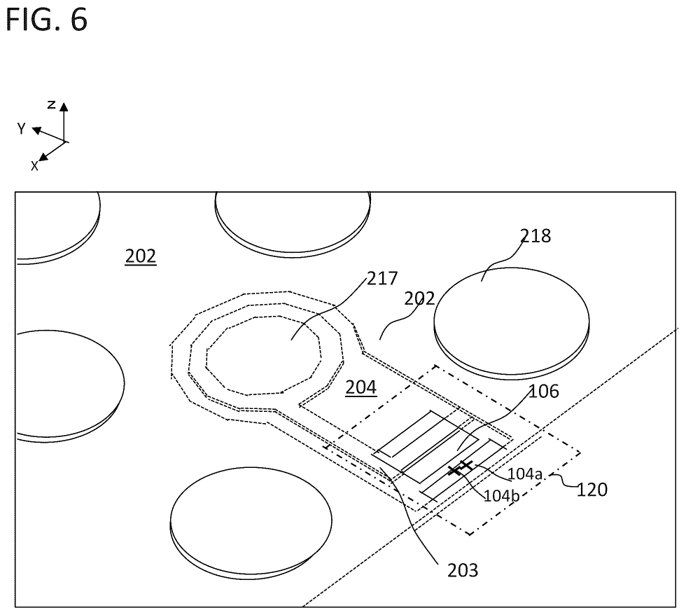

FIG. 6 is a diagram of a schematic exploded view illustrating the wiring 203 of the first wiring layer 213 of the second chip 201 in FIG. 5B and the openings 106 and Josephson junctions 104a and 104b of the wiring layer 213 of the first chip 101 superimposed. In FIG. 6, an area surrounded by 120 dotted lines is the wiring pattern of the first wiring layer of the second chip 201 shown in FIG. 4B and the wiring pattern of the first chip 101 that is flip-chip mounted opposite the first wiring layer of the second chip 201 (SQUID including Josephson junctions 104a and 104b (including loops). As shown in FIG. 6, the wiring 203 of the first wiring layer of the second chip 201 is connected to the terminal (pad) 217 at one end, bent at a right angle at one side of the opening 106 in the wiring layer of the first chip 101, and connected to the ground plane 202 across the opening 106. A gap (void) 204 is provided between the wiring 203 and the ground 202, exposing the surface of the substrate of the second chip 201. The ground (ground plane) 202 to which one end of the wiring 203 is connected surrounds the opening 106 of the quantum bit circuit (SQUID) and the first chip 101, extends along the wiring 203 to the terminal 217 to which the wiring 203 connects, surrounds the terminal 217, and reaches the connection point with one end of the wiring 203. Reference numeral 218 corresponds to a bump 214 (FIG. 5) that connects the ground surface 102 of the first chip 101 and the ground surface 202 of the second chip 201. Although not limited, in the example of FIG. 6, the first wiring layer 213 (such as ground plane 202 and wiring 203) is made of superconducting material.

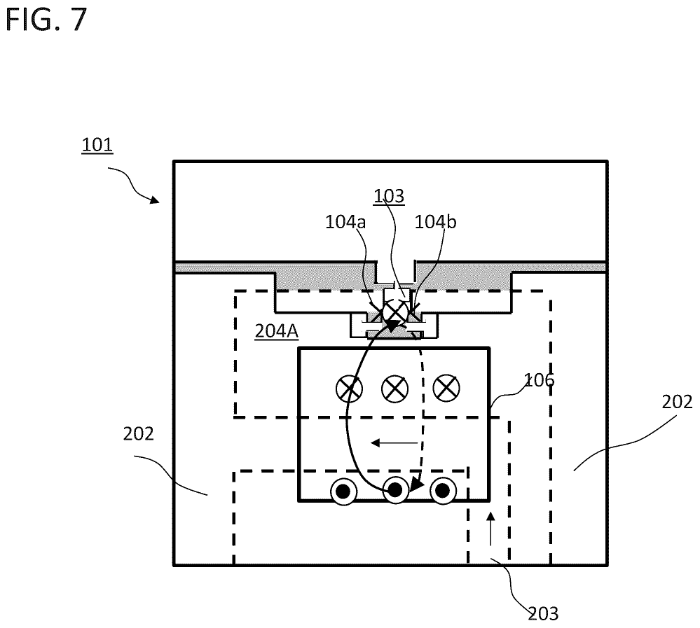

FIG. 7 illustrates a wiring pattern of the second chip 201 in the area enclosed by the single-dotted line 120 in FIG. 6 and a wiring layer of the first chip 101 flip-chip-mounted opposite the second chip 201. In FIG. 7, the wiring 203, etc. of the first wiring layer of the second chip 201 on an underside of the wiring layer of the first chip 101 is shown as virtual lines (dashed lines). As shown in FIG. 7, when a control current flows from the terminal 217 (FIG. 6) to the wiring 203 of the first wiring layer of the second chip 201 along a direction indicated by an arrow, a magnetic field H (magnetic field B=μH, where μ is permeability) is generated according to the following Ampere's law (shown in integral form in Equation (6)).

$${\int }_{\partial S} Hdl = {\int }_{S} j d S \qquad ( 6 )$$

where H is a magnetic field strength, j is a current density, dl is a linear vector, dS is a surface area element (vector), and ∂S is a boundary of the surface area S. A portion of the magnetic field H extends through the opening 106 of the first chip 101 to an interior of the substrate 112 of the first chip 101. A portion of the magnetic field that spreads to the substrate 112 of the first chip 101 becomes a component that penetrates the SQUID loop of the first chip 101 (Josephson junctions 104a, 104b, wiring (electrodes) 103, and the half-rectangular ground electrode 108). The magnetic field penetrating the SQUID loop of the first chip 101 returns around the wiring 203, which is grounded at one end of the second chip 201, forming a closed loop.

In the example of FIG. 7, in operation, when a current (supplied to the terminal 217 from an unshown signal source) flows along a direction indicated by an arrow to the wiring 203 with one end thereof grounded in the second chip 201, a magnetic field is generated that penetrates from the opening 106 in the wiring layer of the first chip 101 in the upward direction from below a paper surface through the substrate 112 of the first chip 101. The magnetic field goes around a top of the wiring 203 of the second chip 201, penetrates through the SQUID loop including the Josephson junctions 104a and 104b of the first chip 101 from the top of the paper to the bottom, passes under the wiring 203 of the second chip 201 and through the opening 106 in the wiring layer of the first chip 101 to the bottom of the paper to the top, which constitutes a closed loop. Since the closed loops of the magnetic fields involved in coupling with the SQUID loop all have components in the same direction, the magnetic field coupling can be increased by superposition of the magnetic fields.

In general, the larger a distance between a wiring (coil) to which a current is applied to generate a magnetic field and a SQUID loop, the smaller a magnetic field coupling strength between the wiring (coil) and the SQUID loop. According to the present disclosure, even when a distance between the wiring 203 of the second chip 201 and the SQUID loop is increased, the magnetic field coupling strength can be kept equal or a decrease in the magnetic field coupling strength can be suppressed, by setting (e.g., increasing) a value of an applied current. Alternatively, the magnetic field coupling strength can be increased and the applied current can be decreased. Also, by increasing the distance between the wiring 203 of the second chip 201 and the SQUID loop, an effect of unintended capacitance can be suppressed.

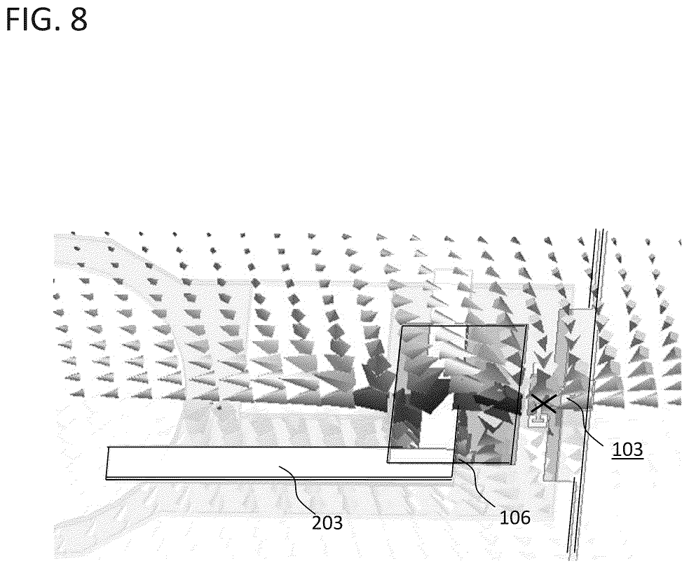

FIG. 8 shows a simulation result of a magnetic field distribution around the opening 106 of the wiring layer 113 of the first chip 101 by a electro-magnetic simulator. Since the magnetic field is an alternating magnetic field, an arrow direction changes according to a phase of the control current.

Generally, when a distance between a coil to apply a magnetic field and the qubit gets closer, an internal Q-value of the qubit deteriorates. According to the present disclosure, it is possible to increase the distance between the wiring 203 of the second chip 201 and the SQUID loop of the first chip 101, while keeping the magnetic field coupling equivalent. As a result, the distance between the wiring 203 and the qubit circuit 105 becomes larger to improve an internal Q-value of the qubit circuit 105 of the first chip 101.

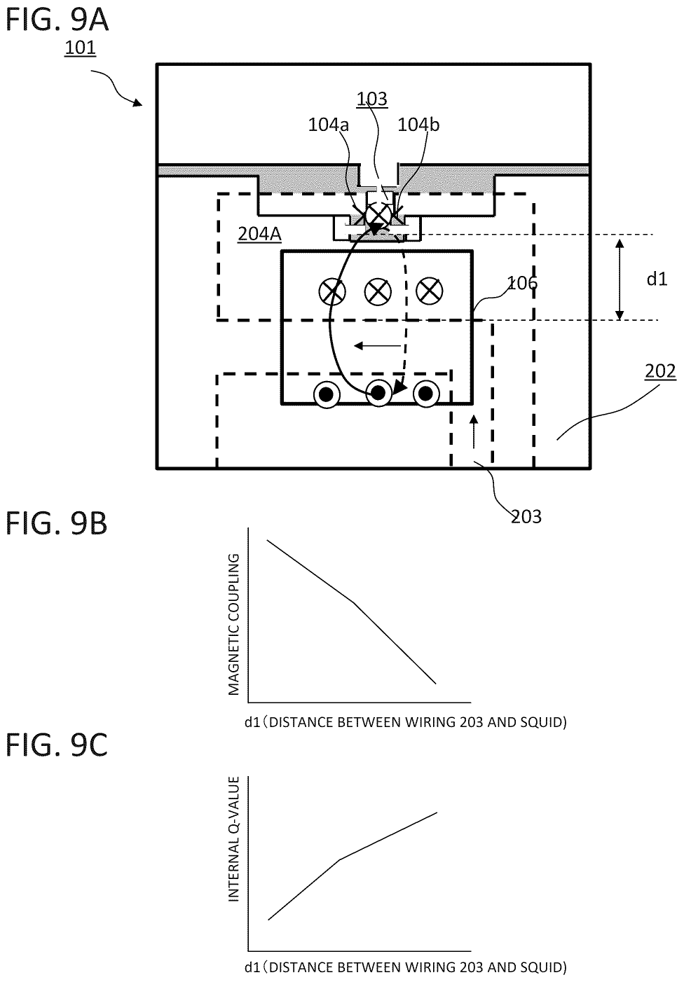

FIG. 9A shows a distance d1 between the wiring 203 of the second chip 201 and the SQUID of the first chip 101 in FIG. 7. FIGS. 9B and 9C illustrate a relationship between the distance d1 and the magnetic field coupling and a relationship between the distance d1 and the internal Q-value. As shown in FIG. 9B, as the distance d1 becomes larger, the magnetic field coupling becomes weak (small). As shown in FIG. 9C, when the distance d1 is large, the internal Q-value of the qubit circuit 105 increases.

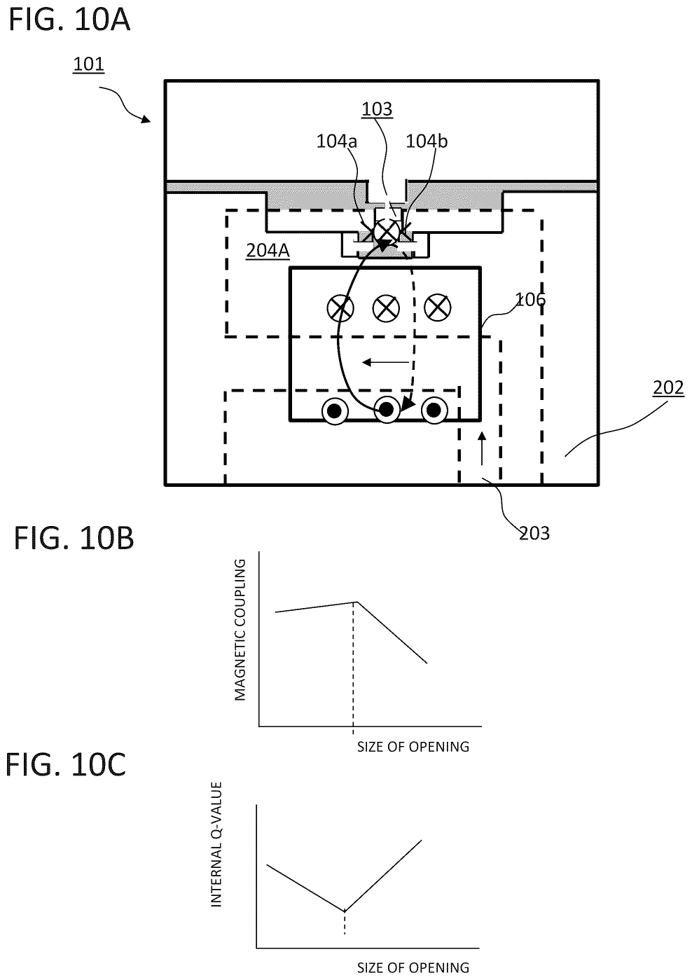

FIGS. 10B and 10C illustrate a relationship between a size (e.g., area) of the opening 106 in the wiring layer 113 of the first chip 10 and the magnetic field coupling and a relationship between the size and the internal Q-value. FIG. 10A shows an area of the opening 106 as the size thereof. As shown in FIG. 10B, as the size of the opening 106 increases, the magnetic field coupling becomes strong, reaching a maximum at a certain size (e.g., area), and thereafter, the magnetic field coupling becomes weak as the size of opening 106 increases. As shown in FIG. 10C, as the size of the opening 106 increases, the internal Q-value of the qubit circuit 105 decreases, reaching a minimum at a certain size (e.g., area), and thereafter the internal Q-value of the qubit circuit 105 increases with increase in the size of the opening 106.

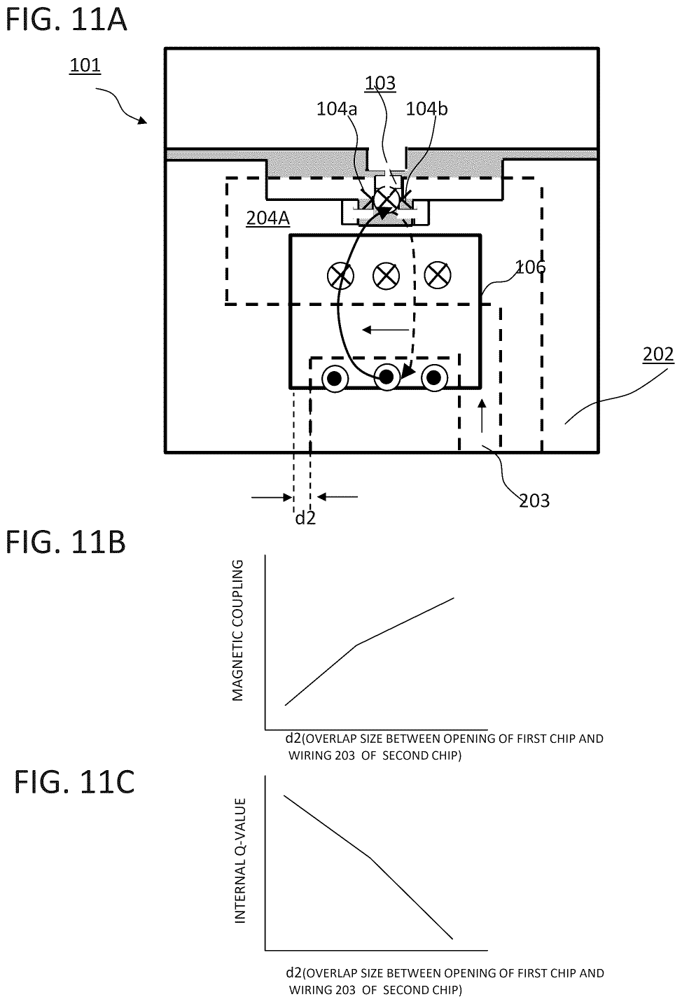

FIG. 11A shows a distance d2 as a size of an overlap between the opening 106 of the wiring layer 113 of the first chip 101 and the wiring 203 of the second chip FIGS. 11B and 11C illustrate a relationship between the distance d2 (the size of the overlap between the opening 106 of the first chip 101 and the wiring 203 of the second chip 201) and the magnetic field coupling (the larger the better), and a relationship between the distance d2 (the size of the overlap between the opening 106 of the first chip 101 and the wiring 203 of the second chip 201) and the internal Q-value (the larger the better). As shown in FIG. 11B, when the distance d2 becomes large, the magnetic field coupling becomes strong (Note that a rate of increase (slope) of the magnetic field coupling changes at a certain value of the distance d2). As shown in FIG. 11C, when the distance d2 becomes large, the internal Q-value of the qubit circuit 105 decreases (a rate of decrease of the internal Q-value varies with a certain value of the distance d2). For this distance d2, there is a trade-off between the magnetic field coupling and the internal Q-value: when one increases, the other decreases.

As the shape of the opening 106 of the wiring layer 113 of the first chip 101, an example of a rectangle with a long side parallel to a longitudinal direction of the wiring 203 is shown, but it may be a square or an abbreviated square, or a rectangle with a short side parallel to the longitudinal direction of the wiring 203 of the second chip 201. Alternatively, the shape of the opening 106 of the wiring layer 113 of the first chip 101 may be circular or oval, triangular or polygonal. In the case of a triangular opening 106, a bottom edge may be parallel to the longitudinal direction of the wiring 203.

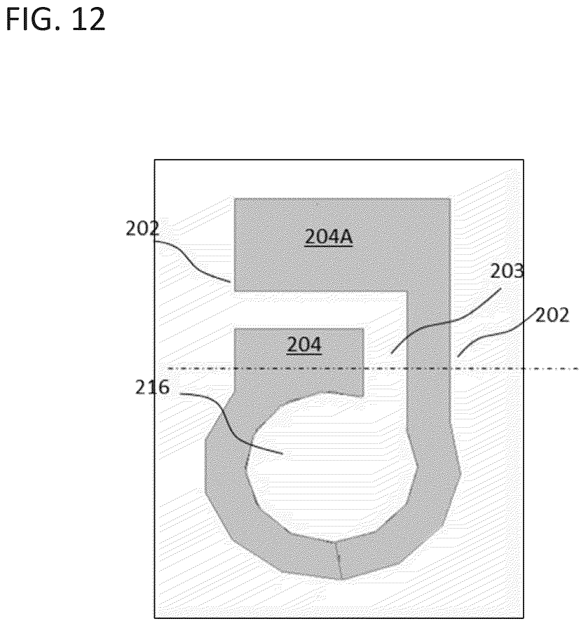

FIG. 12 schematically illustrates an example layout of the wiring 203 of the first wiring layer 213 of the second chip 201, the ground pattern 202 to which one end of the wiring 203 connects, and the terminal 217 to which the other end of the wiring 203 connects. The area 204A (where the wiring layer (metal layer) is deleted) surrounded by the wiring 203 and the ground pattern 202 has no limitation in shape if it overlaps with the SQUID loop of the first chip 101 when the wiring layer 113 of the first chip 101 is mounted opposite to the first wiring layer 213 of the second chip 201. In addition, there is no restriction on a shape (pattern surrounding the via 216) below a single-dotted line in FIG. 12 and it is arbitrary.

The above examples and/or embodiments may be annexed as the following supplementary notes (abbreviated as notes) (but not limited thereto).

(Note 1) A superconducting quantum circuit apparatus comprises:
a first chip that includes a qubit circuit including a superconducting quantum interference device (SQUID) in a wiring layer formed on a substrate of the first chip; and
a second chip that includes a wiring layer on a first side of a substrate of the second chip, the wiring layer on the first side being disposed opposed to the wiring layer of the first chip,
wherein the wiring layer of the first chip has an opening juxtaposed with the SQUID of the qubit circuit, and
wherein the wiring layer on the first side of the second chip includes a first wiring having one end connected to a terminal, and in a region opposite at least the opening of the first chip, being extended along the qubit circuit of the first chip, the first wiring having other end connected to a ground pattern arranged in the wiring layer on the first side of the second chip.

(Note 2) In the superconducting quantum circuit apparatus of Note 1, the SQUID in the first chip includes a Josephson junction with one end to a superconducting wiring of the qubit circuit and other end connected to a ground electrode.

(Note 3) In the superconducting quantum circuit apparatus of Note 1 or 2, in the first chip, the superconducting wiring of the qubit circuit, the ground electrode, and two Josephson junctions connected in parallel between the superconducting wiring and the ground electrode constitute a loop of the SQUID, the ground electrode located at a predetermined position spaced apart from the qubit circuit.

(Note 4) The superconducting quantum circuit apparatus of any of Notes 1 to 3, in the first chip, the opening is located adjacent to the ground electrode.

(Note 5) The superconducting quantum circuit apparatus of any of Notes 1 to 4, in the second chip, a region surrounded by the first wiring and the ground pattern to which the other end of the first wiring connects includes therein or partially overlaps a region where the SQUID of the first chip is disposed.

(Note 6) The superconducting quantum circuit apparatus of any of Notes 1 to 5, in the second chip, the first wiring is bent at a location overlapping the opening of the first chip, traverses an area opposed to the opening of the first chip parallel to the SQUID of the qubit circuit of the first chip, and is connected to the ground pattern in the wiring layer on the first side of the second chip, the ground pattern located on an edge side of the opening of the first chip.

(Note 7) The superconducting quantum circuit apparatus of Note 6, in the second chip, the ground pattern to which the other end of the first wiring connects surrounds a region opposed to a region where at least the SQUID of the first chip is disposed, is extended beyond a location where the first wiring is bent, and further extended with an side edge thereof opposed to the first wiring toward a side of the terminal to which the one end of the first wiring connects.

(Note 8) The superconducting quantum circuit apparatus of Note 6, in the second chip, the ground pattern to which the other end of the first wiring connects, includes a connection portion with the other end of the first wiring, the connection portion partially overlapping a region where the opening in the wiring layer of the first chip is located.

(Note 9) The superconducting quantum circuit apparatus of any one of Notes 1 to 8, when operated, the terminal of the second chip is supplied with a signal from a signal source and a magnetic field generated by a current flowing in the first wiring passes through the opening in the wiring layer of the first chip and penetrate the SQUID loop of the first chip.

The above disclosure of PTL 1 shall be incorporated herein by reference. Within the framework of the entire disclosure (including the scope of claims), furthermore, based on the basic technical concept, changes and adjustments to the embodiments and examples are possible. In addition, various combinations and selections of various disclosed elements (including each element of each claim, each element of each example, each element of each drawing, etc.) are possible within the framework of the claims of the present disclosure. In other words, the present disclosure includes various variations such as transformations and modifications that a person skilled in the art would be able to make in accordance with the entire disclosure and technical concept, including the scope of the claims.

What is claimed is:

1. A superconducting quantum circuit apparatus comprises:
a first chip that includes a qubit circuit including a superconducting quantum interference device (SQUID) in a wiring layer formed on a substrate of the first chip; and
a second chip that includes a wiring layer on a first side of a substrate of the second chip, the wiring layer on the first side being disposed opposed to the wiring layer of the first chip,
wherein the wiring layer of the first chip has an opening juxtaposed with the SQUID of the qubit circuit, and
wherein the wiring layer on the first side of the second chip includes a first wiring having one end connected to a terminal, and in a region opposite at least the opening of the first chip, being extended along the qubit circuit of the first chip, the first wiring having other end connected to a ground pattern arranged in the wiring layer on the first side of the second chip.

2. The superconducting quantum circuit apparatus according to claim 1, wherein the SQUID in the first chip includes a Josephson junction with one end to a superconducting wiring of the qubit circuit and other end connected to a ground electrode.

3. The superconducting quantum circuit apparatus according to claim 2, wherein in the first chip, the superconducting wiring of the qubit circuit, the ground electrode, and two Josephson junctions connected in parallel between the superconducting wiring and the ground electrode constitute a loop of the SQUID, the ground electrode located at a predetermined position spaced apart from the qubit circuit.

4. The superconducting quantum circuit apparatus according to claim 3, wherein in the first chip, the opening is located adjacent to the ground electrode.

5. The superconducting quantum circuit apparatus according to claim 1, wherein in the second chip, a region surrounded by the first wiring and the ground pattern to which the other end of the first wiring connects includes therein or partially overlaps a region where the SQUID of the first chip is disposed.

6. The superconducting quantum circuit apparatus according to claim 1, wherein in the second chip, the first wiring is bent at a location overlapping the opening of the first chip, traverses an area opposed to the opening of the first chip parallel to the SQUID of the qubit circuit of the first chip, and is connected to the ground pattern in the wiring layer on the first side of the second chip, the ground pattern located on an edge side of the opening of the first chip.

7. The superconducting quantum circuit apparatus according to claim 6, wherein in the second chip, the ground pattern to which the other end of the first wiring connects surrounds a region opposed to a region where at least the SQUID of the first chip is disposed, is extended beyond a location where the first wiring is bent, and further extended with an side edge thereof opposed to the first wiring toward a side of the terminal to which the one end of the first wiring connects.

8. The superconducting quantum circuit apparatus according to claim 6, wherein in the second chip, the ground pattern to which the other end of the first wiring connects, includes a connection portion with the other end of the first wiring, the connection portion partially overlapping a region where the opening in the wiring layer of the first chip is located.

9. The superconducting quantum circuit apparatus according to claim 1, wherein when operated, the terminal of the second chip is supplied with a signal from a signal source and a magnetic field generated by a current flowing in the first wiring passes through the opening in the wiring layer of the first chip and penetrate the SQUID loop of the first chip.

10. The superconducting quantum circuit apparatus according to claim 1, wherein the first wiring is connected to a via pad arranged on wiring layer on the first side of the substrate of the second chip, the via pad connected though a via penetrating the substrate of the second chip to the terminal arranged on a second side of the substrate of the second chip opposite to the first side thereof.

11. The superconducting quantum circuit apparatus according to claim 1, including one or more bumps between the wiring layer of the first chip and the wiring layer on the first side of the substrate of the second chip, wherein when operated, a signal to or from the qubit circuit of the first chip is transmitted, through one of the one or more bumps, from or to a pad provided in the wiring layer on the first side of the substrate of the second chip, the pad connected though a via penetrating the substrate of the second chip to a terminal arranged on a second side of the substrate of the second chip opposite to the first side thereof.
